(19) United States
(12) Patent Application Publication
(10) Pub. No.: US 2014/0096998 A1
(43) Pub. Date: Apr. 10, 2014

(54) Electrical Contact Pad

(71) Applicant: Infineon Technologies AG, Neubiberg (DE)

(72) Inventors: Erwin Johann Vogl, Hallbergmoos (DE); Markus Winkler, Muenchen (DE); Markus Zundel, Egmating (DE)

(73) Assignee: Infineon Technologies AG, Neubiberg (DE)

(21) Appl. No.: 14/049,265

(22) Filed: Oct. 9, 2013

(30) Foreign Application Priority Data
Oct. 9, 2012 (DE) 10 2012 019 782.9

(51) Int. Cl. H01L 23/49

(52) U.S. Cl. CPC H01L 23/49
USPC 174/126.1

(57) ABSTRACT

In various embodiments, an electrical contact pad is provided, wherein the electrical contact pad has at least two regions which are electrically separated from one another.

### CROSS-REFERENCE TO RELATED APPLICATION

This application claims priority to German Patent Application Serial No. 10 2012 019 782.9, which was filed Oct. 9, 2012, and is incorporated herein by reference in its entirety.

### TECHNICAL FIELD

Various embodiments relate to an electrical contact pad.

### BACKGROUND

The terminals (pins) which are externally visible in an electronic circuit or semiconductor housing are connected to the chip terminals (bonding islands or pads) by way of bonding wires in the interior of the housing. The pads are for their part metallic contacts, which are electrically connected to the semiconductor by means of ohmic contacts. The task of the bonding wire is to form the electrical connection between the actual integrated circuit or the bare component and the housing. During and after the production of a chip, it is necessary to test the chip. During testing, it is necessary to carry out special measurements on the chip in order to check its correct operation. For this purpose, separate potentials are often required for the measurement, but these are no longer required later during “regular” operation of the chip. For this purpose, provision is generally made of additional bonding pads, which are then connected after testing to a bonding wire, for example, and are therefore electrically short-circuited. This solution has the disadvantage that at least two bonding pads and one bonding wire have to be provided. This leads to a higher demand for chip area and to higher material costs.

### SUMMARY

In various embodiments, an electrical contact pad is provided, wherein the electrical contact pad has at least two regions which are electrically separated from one another.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows an electrical contact pad, with a line showing the electrical separation between the two regions. Here, the line has a straight form, for example, or additionally has a curve.

FIG. 2 shows an electrical contact pad, with a line showing the electrical separation between the two regions. Here, the line has a curved form, for example, with a plurality of curves.

FIG. 3 shows differs from FIG. 1 and FIG. 2 in that, in this embodiment, the line has a meandering or sinuous form with very many turns and/or curves.

### DESCRIPTION

Embodiments of the invention will be explained in more detail hereinbelow, with reference to the accompanying figures. However, the invention is not restricted to the embodiments described specifically, but rather can be modified and varied in a suitable manner. It is within the scope of the invention to suitably combine individual features and combinations of features of one embodiment with features and combinations of features of another embodiment in order to arrive at further embodiments according to the invention.

Before the embodiments of the present invention are explained in more detail hereinbelow with reference to the figures, it is noted that the same elements in the figures are provided with the same or similar reference signs and that a repeated description of these elements is omitted. Furthermore, the figures are not necessarily true to scale. The focus lies instead on explaining the basic principle.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Various embodiments provide an electrical contact pad which may reduce chip area and costs.

In various embodiments, the electrical contact pad is subdivided into at least two regions which are electrically separated from one another. The regions may initially be at different potentials. The potential halves are short-circuited again by applying a bonding wire or clip. One effect of this solution may be that, in its productive application, the chip does not require two or more contact pads, also known as bonding pads, which are then short-circuited by means of a bonding wire. As a result, the required chip area may be reduced considerably and material costs may be reduced.

In a further embodiment, the at least two regions of the electrical contact pad which are separated from one another may be contact-connected to one another in contact regions by means of an electrical conductor. Contact regions preferably form along a topographical separation line of the at least two regions of the electrical contact pad, since there the separated regions lie close together and therefore may be bridged very readily and therefore can be electrically contact-connected.

In a further embodiment, the electrical conductor for contact-connecting the electrically separated regions of the electrical contact pad is a bonding wire. Bonding wires are readily obtainable and may be produced at low cost. Bonding wires usually consist of gold or else alloyed or doped gold, but aluminum with a (small) silicon proportion (AlSil) and copper are also used.

In a further embodiment, the bonding wire forms a contact area on the surface of the contact pad during bonding, which contact area electrically connects the at least two regions which are electrically separated from one another to one another. The various method variants for the sequential contact-connecting or bonding of semiconductor components may be thermocompression bonding (TC bonding), thermosonic ball-wedge bonding (TS bonding) and/or ultrasonic wedge-wedge bonding (US bonding). The methods mentioned first generally operate using gold wire, and US bonding may be carried out using aluminum or aluminum-silicon wire (AlSil). A further variant of bonding in accordance with various embodiments is bonding using the double stitch method. Here, the bonding wire is secured on a contact of an IC, for example, is then drawn to form a further contact of the IC, where it is likewise secured, and is then drawn away from the IC onto an outer contact and secured.

In a further embodiment, the at least two regions which are electrically separated from one another are topographically electrically separated from one another by a straight line and/or by a meandering or sinuous line, within which there is arranged no conducting material. This arrangement affords the advantage that the number of potential contact regions between the regions of the electrical contact pad may be set by means of the line profile of the separating region (no metallization, i.e. non-conducting).

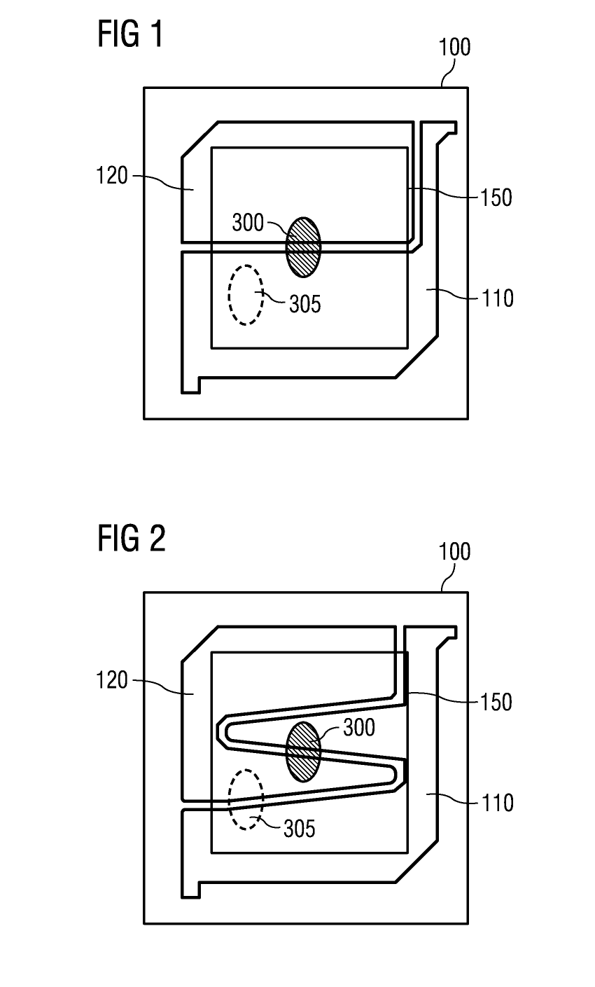

FIG. 1 shows an electrical contact pad 100, a line 150 showing the electrical separation between the two regions 110, 120. The electrical contact pad is separated in the front end during the production of integrated circuits. There, special measurements can then be carried out on the separated contact pad 100. Since these special measurements no longer have to be carried out later, the regions 110, 120 of the electrical contact pad 100 may be short-circuited again. In this case, the regions 110, 120 of the electrical contact pad 100 may be at the same or different potentials, which are then short-circuited. The line 150, which may also be denoted as a gap, indicates the absence of a conducting material. This region may in various embodiments include polyimides, imides or oxides or be filled at least partially with mold compound. Alternatively, this intermediate region or gap region may have a hollow space. The line 150 or the gap may in various embodiments have a width of several nm up to 100 μm. In various embodiments, the line 150 may have a width in the range of 1 μm to 2 μm, or the line 150 may have a width in the range of 2 μm to 5 μm, or the line 150 may have a width in the range of 5 μm to 10 μm, or the line 150 may have a width in the range of 10 μm to 20 μm, or the line 150 may have a width in the range of 20 μm to 50 μm, or the line 150 may have a width in the range of above 50 μm. Here, the line has a straight form, for example, or additionally has a curve. Furthermore, FIG. 1 shows an example of a contact region 300 for the electrical contact-connection of the two regions 110, 120 of the contact pad. The contact regions 300 extend along the line profile 150 and in this respect may have different sizes and/or shapes. In this embodiment, only a few potential contact regions 300 are provided. The risk of a bonding wire being bonded outside the contact region 305 and therefore the regions 110, 120 of the electrical contact pad not being electrically contact-connected is high. Bonding wire or clips usually include gold or else alloyed or doped gold, but aluminum with a silicon proportion (AlSil) and copper are also used. Here, thinner bonding wires allow for narrower pad geometries and therefore higher packing densities. In the field of power electronics, use is made of pure aluminum materials (99.99% Al proportion and higher), and in the case of discrete semiconductors (diodes, transistors) high-purity gold is mostly used (copper wires are currently in the test phase). In the case of power semiconductors for the use of high current loads, use is made of thick wires having diameters of between 100 μm and 500 μm or thick wire ribbons. If this is not adequate, bonding is carried out repeatedly.

FIG. 2 shows an electrical contact pad 100, a line 150 showing the separation between the two regions 110, 120. Here, the line 150 has a curved form with a plurality of curves, for example. Furthermore, FIG. 2 shows an example of a contact region for the electrical contact-connection of the two regions 110, 120 of the contact pad. Contact pads may in various embodiments include copper, copper alloys, gold, gold alloys, aluminum, aluminum alloys. Here, too, the contact regions 300 extend along the line profile 150. In various embodiments, significantly more potential contact regions 300 are provided for the electrical contact-connection of the regions 110, 120. The risk of a bonding wire not causing a short-circuit 305 between the two regions 110, 120 of the electrical contact pad is reduced.

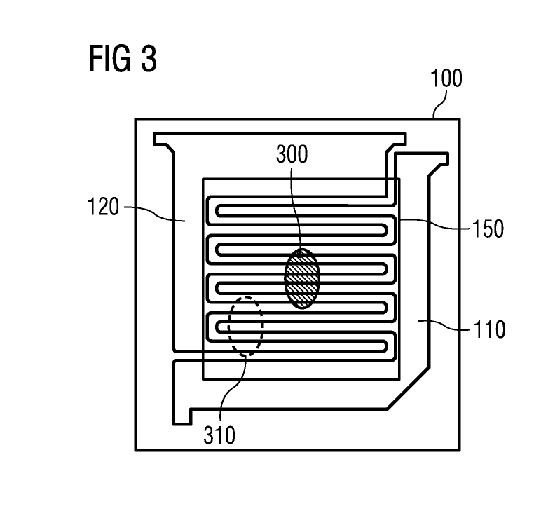

FIG. 3 differs substantially from FIG. 1 and FIG. 2 in that, in various embodiments, the line 150 has a meandering or sinuous form with very many turns and/or curves. Here, too, the contact regions 300 extend along the line profile 150. In various embodiments, the number of potential contact regions 300 for the electrical contact-connection of the regions 110, 120 is therefore virtually at a maximum. The risk of a bonding wire not causing a short-circuit between the two regions 110, 120 of the electrical contact pad is virtually minimized. The contact region 310, too, brings about an electrical contact-connection of the regions 110, 120. In various embodiments, an electrical contact pad may be used which is already at the indicated potential at least to an extent of half, for example is already installed on the chip in the case of a MOSFET and as a source sensor tap. After the electrical contact-connection of the regions 110, 120, the entire region is at source potential. No additional chip areas are therefore required for the contact-connection. The contact pad which is subdivided into regions and is described here can furthermore be used advantageously where various metal lines are to be electrically short-circuited to one another. For example in the case of sensor structures implemented on a chip (ON chip), in the case of a plurality of electrodes in the trench (3 polys or more per trench) or in the case of purposefully desired connections from trench to trench, electrical connections may be made by means of the electrical contact-connection of regions 110, 120 of an electrical contact pad 100. The electrical contact pad 100 with regions 110, 120 which are electrically separated from one another may be used for the widest variety of components, for example for diodes, MOS, IGBTs, ICs, but also for vertically conducting MOS and phase/trench transistors with one or more electrodes in the trench. The use of said contact pad is also particularly advantageous for DualPoly and TrenchMOS.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. An electrical contact pad,
wherein the electrical contact pad has at least two regions which are electrically separated from one another.

2. The electrical contact pad of claim 1,
wherein the at least two regions which are separated from one another are contact-connected to one another in contact regions by means of an electrical conductor.

3. The electrical contact pad of claim 2,
wherein the electrical conductor is a bonding wire or a clip.

4. The electrical contact pad of claim 3,
wherein the bonding wire forms a contact area in the contact zone of the separated regions during bonding, which contact area electrically connects the at least two regions which are electrically separated from one another to one another.

5. The electrical contact pad as claimed in one of the preceding claims claim 1,
wherein the separation of the at least two regions which are electrically separated from one another is shown topographically substantially by a straight line and/or by a meandering line and/or by a sinuous line.

6. A plurality of electrical contact pads,
wherein each electrical contact pad has at least two regions which are electrically separated from one another; and
wherein the plurality of electrical contact pads are electrically contact-connected to one another in contact regions by means of an electrical conductor.
